(19) United States
(12) Patent Application Publication
(10) Pub. No.: US 2025/0243938 A1
(43) Pub. Date: Jul. 31, 2025

(54) COATED WEAR SLEEVE FOR DYNAMIC SHAFT

(71) Applicant: Caterpillar Inc., Peoria, IL (US)

(72) Inventors: Elmer Sanchez Zanoria, Dunlap, IL (US); Keith Harmeyer, Lafayette, IN (US); Daniel Joshua Smith, Peoria, IL (US); Otto James Rajtora, III, East Peoria, IL (US); Jeff A. Jensen, Dunlap, IL (US)

(73) Assignee: Caterpillar Inc., Peoria, IL (US)

(21) Appl. No.: 18/423,526

(22) Filed: Jan. 26, 2024

(51) Int. Cl. F16J 15/3252; F16L 57/06

(52) U.S. Cl. CPC F16J 15/3252; F16L 57/06

(57) ABSTRACT

An example shaft, such as a crankshaft, has a coated wear sleeve disposed thereon. The coating on the wear sleeve provides tribological and/or mechanical benefits. The coating has a lower coefficient of kinetic friction than a conventional wear sleeve. The coating may further have a relatively high hardness. The coating may include a diamond like carbon (DLC) film or a metal-doped DLC (Me-DLC) film, such as tungsten (W)-doped DLC (W-DLC) film. The coating may be deposited on a bulk portion of the wear sleeve using physical vapor deposition (PVD) or similar processes. The coated wear sleeve is configured to engage and make contact with a static seal. The static seal includes elements that make contact with the coated wear sleeve while the shaft and coated wear sleeve rotate. The reduced friction, due to the coating, enhances the lifetime of the static seal.

### TECHNICAL FIELD

The present disclosure relates to wear sleeves of shafts. More specifically, the present disclosure relates to wear sleeves with thin sacrificial coatings for crankshafts.

### BACKGROUND

Machines are in widespread use in construction, mining, paving, forestry, and other similar industries. These machines are used to perform various tasks, such as lifting, moving, dumping etc. of materials, such as dirt. These machines often have internal combustion engines that oxidize hydrocarbons, such as diesel, to power the machine. The internal combustion engines, have cylinders, in which the hydrocarbon fuels are combusted in a timed periodic fashion to cause reciprocating motion of a piston traversing at least part of the length of the cylinder. This type of linear reciprocating motion is converted to rotational motion by way of a crankshaft. The pistons of the internal combustion engine are mechanically coupled to the crankshaft by way of one or more elements, such as piston rods and bearings.

Typical crankshafts within an internal combustion engine may be subject to harsh operating conditions, such as high heat, high friction, and high stresses. Thus crankshafts, particularly in heavy machinery, can wear out relatively quickly. As a result, it is desirable to operate crankshafts in a lubricated environment. A static seal may be formed around the crankshaft to retain lubrication on the crankshaft and not let the lubrication seep away from the crankshaft. The static seal is disposed in a radial fashion around the crankshaft near one or both ends of the crankshaft. Because of the dynamic nature of the crankshaft during operation, the crankshaft can move both in a radial manner and/or a longitudinal manner. As a result, the crankshaft can contact the static seal, which can lead to wear of the crankshaft where it contacts the static seal. This wear on the crankshaft from contact with the static seal can result in a reduced lifetime of the crankshaft.

An example of providing a protective coating on rotor shaft of an electric motor is described in U.S. Pat. Publication No. 20220320964 (hereinafter referred to as the '964 publication). The '964 publication describes a diamond like carbon sleeve for the electric rotor shaft. However, the approach of the '964 publication is specific to electric motors and would not be applicable to crankshaft applications.

Example embodiments of the present disclosure are directed toward overcoming the deficiencies described above.

### SUMMARY

In an example of the disclosure, a shaft includes a first end and a second end opposing the first end, where the first end and the second end spans a length of the shaft and a wear sleeve disposed proximal to the first end and radially surrounding the shaft. The wear sleeve includes a bulk region having an inner diameter surface and an outer diameter surface opposing the inner diameter surface and a coating disposed on the outer diameter surface, the coating comprising diamond like carbon (DLC).

In another example of the disclosure, a machine includes an engine including a crankshaft with a coated wear sleeve disposed on the crankshaft. The coated wear sleeve includes a bulk region having an inner diameter surface and an outer diameter surface opposing the inner diameter surface and a coating disposed on the outer diameter surface, the coating characterized by having a lower coefficient of static friction than the bulk region.

In yet another example of the disclosure, a method includes forming a bulk region having a ring shape, where the bulk region has an inner surface and an outer surface. The method further includes depositing a coating layer over at least a portion of the outer surface to form a coated wear sleeve, the coating layer including metal-doped diamond-like carbon (Me-DLC).

### BRIEF DESCRIPTION OF DRAWINGS

FIG. 1 is a schematic illustration of an example machine, according to examples of the disclosure.

FIG. 2 is a schematic illustration of an example environment with crankshaft with a coated wear sleeve of the machine as depicted in FIG. 1, according to examples of the disclosure.

FIG. 3 is a schematic illustration of an end of the crankshaft of FIG. 2 within a housing with a static seal and a coated wear sleeve, according to examples of the disclosure.

FIG. 4 is a schematic illustration of a coated wear sleeve, according to examples of the disclosure.

FIG. 5 is a sectional illustration of an example environment with a wear sleeve in contact with a static seal element, according to examples of the disclosure.

FIG. 6 is an example method to form the wear sleeve of FIG. 4, according to examples of the disclosure.

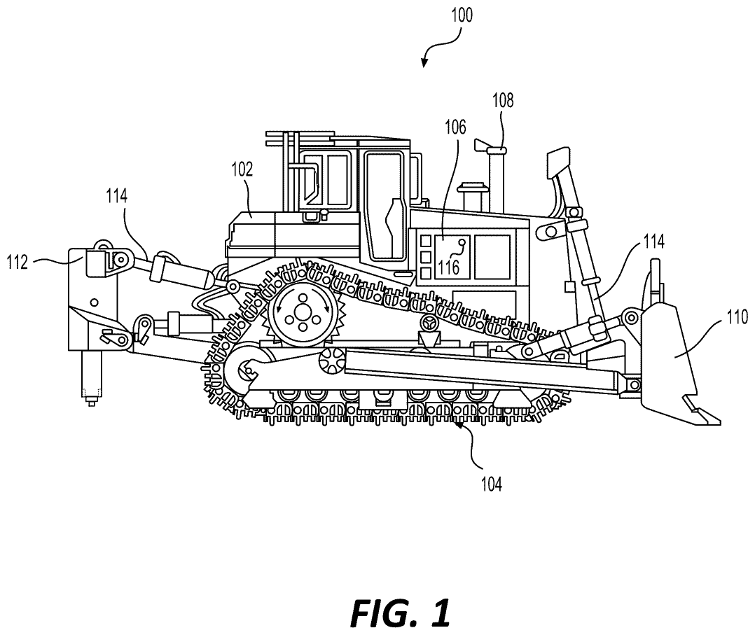

### DETAILED DESCRIPTION

Wherever possible, the same reference numbers will be used throughout the drawings to refer to the same or like parts. FIG. 1 is a schematic illustration of an example machine 100, according to examples of the disclosure. Although the machine 100 is depicted as a dozer, it should be understood that the machine 100 may be of any suitable type, such as those used in construction, farming, mining, paving, transportation, or the like. In other examples, the machine 100 may be any suitable machine 100, such as a loader, an excavator, a tank, a backhoe, a drilling machine, a trencher, a combine, or any other on-highway or off-highway vehicle.

It should still further be understood that the systems, apparatus, and methods disclosed herein may pertain to any internal combustion engine, and not just to engines for machines. For example, the coated wear sleeve for a shaft, as disclosed herein, may be applied to any variety of engines, such as marine engines, train engines, generator engines, car engines, motorcycle engines, yard tool engines, or the like. Further still, although discussed in the context of crankshafts, it should be understood that the coated wear sleeve may be applied to any variety of shafts, such as rotor shafts, transmission shafts, drive shafts, camshafts, or the like.

The machine 100 includes a frame 102 on which other elements of the machine 100 are mounted. The machine 100 includes a propulsion system 104, such as a track chain assembly, as shown. Alternatively, the machine 100 may have any other suitable type of propulsion system 104, such as wheels and tires. The machine 100 further includes an engine 106, such as an internal combustion engine using hydrocarbon fuels. Alternatively, the machine 100 may be an electrically powered machine, with shaft(s) having a coated wear sleeve, as disclosed herein.

The machine 100 includes an exhaust system 108 to exhaust the byproducts of the combustion reactions taking place within the engine 106, such as within cylinders (not shown) of the engine 106. The machine 100 further includes one or more work systems 110, 112 that are movable by one or more hydraulic systems 114. The machine 100 also includes a transmission system (not shown) that mechanically couples the engine 106 to the propulsion system 104.

According to examples of the disclosure, any component of the machine 100, including any variety of components of the propulsion system 104, the exhaust system 108, the work systems 110, the hydraulic systems 114, the transmission, etc., may interact with the engine 106 with a crankshaft with a coated wear sleeve, as disclosed herein. It should further be understood that the various components of the machine 100, other than the engine 106, may also include one or more shafts that may have a coated wear sleeve disposed thereon for any purpose, such as to extend the wear life of the shaft(s). For example, the transmission may include a variety of shafts, such as shafts on which gears are disposed, that may be protected with the wear sleeves disclosed herein. As another example, the propulsion system 104 may include one or more shafts, such as shafts connected to rotating members of the propulsion system 104, which may be protected from wear from contact with other parts of the machine 100 using the coated wear sleeves disclosed here.

The engine 106 may be any variety of engine, such as an internal combustion engine with combustion cylinders (not shown) coupled with pistons (not shown) configured to move within the combustion cylinders. The engine 106 may operate on any variety of fuels including, diesel, gasoline, natural gas, liquified petroleum gas, compressed natural gas, hydrogen, combinations thereof, or the like. The engine 106 may operate in a manner where fuel and air are injected into the cylinder, then the air and fuel mixture is compressed within the cylinder and ignited, followed by the piston extending outward from the cylinder to complete its stroke, and the exhaust (e.g., spent fuel and reacted gases) is discharged from the cylinder. The engine 106 may operate in the preceding manner or in other similar manner. For example, the engine 106 may operate as a four-stroke engine, a two-stroke engine, or the like.

The engine 106 may be of any suitable size and/or configuration. For example, the engine 106 may have anywhere from 1 to 30 cylinders. In terms of displacement, the engine 106 may be anywhere from 40 cubic centimeters (cc) to 43 liters (L). The cylinders of the engine 106 may have any suitable orientation, such as inline, V-configuration, W-configuration, or the like. It should be understood that the systems, apparatus, and methods, as disclosed here, apply to any type of engine size, cylinder count, and/or configuration.

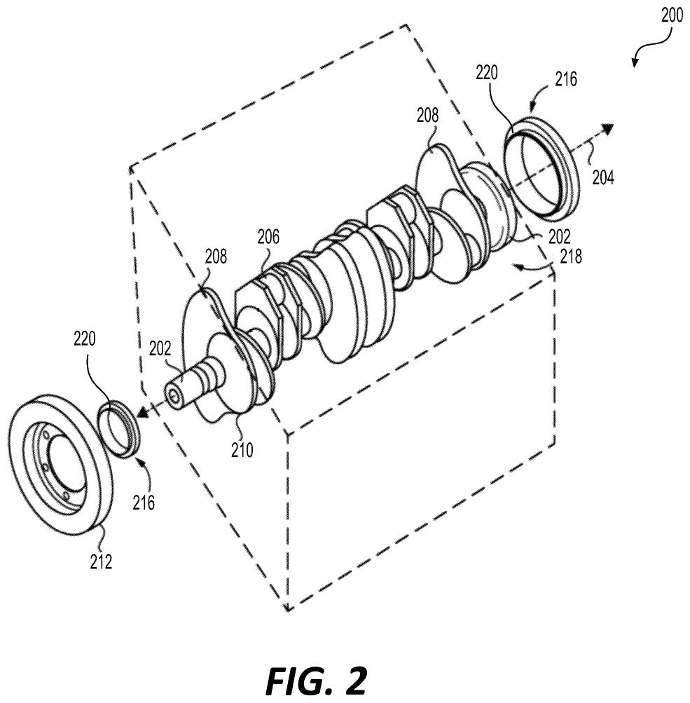

In examples of the disclosure, the engine 106 may include a crankshaft 116 to which the pistons of the engine 106 are coupled. The crankshaft 116 converts the linear reciprocating motion of the pistons to rotational motion that can be transmitted to the propulsion system 104 via the transmission. The crankshaft 116 may be of any suitable size, shape, length, and/or configuration. According to examples of the disclosure, the crankshaft 116 may include a wear sleeve with a coating disposed thereon. The coated wear sleeve, as is described further in conjunction with FIG. 2, reduces the wear of the crankshaft 116, as well as a static seal proximal to one or both ends of the crankshaft 116.

FIG. 2 is a schematic illustration of an example environment 200 with crankshaft 202 with a coated wear sleeve 220 of the machine 100 as depicted in FIG. 1, according to examples of the disclosure. The environment 200 may be within the engine 106, proximal to the pistons of the engine 106. The crankshaft 202 may be an example of crankshaft 116. The crankshaft 202 has a center axis 204 along its length, such as along the journal of the crankshaft 202. The crankshaft 202 may rotate around its center axis 204.

The crankshaft 202 may have a variety of elements disposed thereon, such as bearing 206, balancing webs 208, fan pulley 210, and flywheel 212 ring gear. The crankshaft 202 may also include one or more static seal(s) 216 to hold fluid(s), such as lubricant, in proximity of the crankshaft 202, such as in a region 218. According to examples of the disclosure, the crankshaft 202 may further include one or more coated wear sleeve(s) 220. The coated wear sleeve 220 may include a coating to reduce wear of the static seal 216 when contacting the coated wear sleeve 220. As depicted, in some examples, there may be two static seals 216 on either side of the crankshaft 202, along with corresponding respective wear sleeves 220. In other cases, there may only be one static seal 216 and/or wear sleeve 220.

The pistons of engine 106 of the machine 100 may be connected to the bearing 206, such as via shafts/rods of the piston, to convert reciprocating motion of the piston to rotational motion that is to be transmitted to the propulsion system 104 via a transmission of the machine 100. The bearing 206 allows for a freedom of rotation at the point (e.g., crankpin) at which the piston rod is connected to the crankshaft 202. The bearings 206 may be of any suitable type and may include any suitable subcomponents, such as one or more journals, balls, rollers, etc. Although crankshaft 202 is depicted as having four bearings 206, it should be understood that there any be any number of suitable bearings 206. The number of bearings 206 may, in some cases, equal the number of cylinders of the engine 106. For example, a 6-cylinder inline engine may have six bearings 206 disposed on the crankshaft 202.

The balancing webs 208 of the crankshaft 202 may provide a weight balance, or rotational momentum balance, to the crankshaft 202. In other words, the balancing webs 208 allow for optimizing the moment of inertia of the crankshaft 202 to reduce off-balance vibrations and improve the smoothness of operation of the crankshaft 202. The balancing webs 208 allow for relatively precise weight distribution around the axis of rotation or center axis 204 of the crankshaft. Thus, the balancing web improves the overall efficiency of the power transfer from the reciprocating motion of the pistons to the rotational motion of the crankshaft 202. It should be understood that the crankshaft 202 may include any number of balancing webs 208, as needed to reduce rotational vibration.

The fan pulley 210 may be any element that allows a belt to be driven from the crankshaft 202. For example, a belt may be wrapped taught around the belt pulley 210 to drive another rotational motion component, such as a fan. However, the fan pulley 210 is not limited to just driving fans. Indeed, the fan pulley 210 may be used to drive a belt for any purpose, such as timing or the like. Although a single fan pulley 210 is depicted for crankshaft 202, there may be any suitable number of fan pulley(s) 210.

The flywheel 212 stores mechanical energy. In other words, the flywheel 212 gains rotational momentum as the crankshaft 202 rotational velocity increases. Due to conservation of rotational momentum (e.g., rotational inertia), the flywheel 212 can store energy that is already imparted to it via the crankshaft 202. The operation of the flywheel 212 is based in part on its moment of inertia, which depends on its mass and shape, and on its rotational speed. The flywheel 212 provides stability to the rotational motion of the crankshaft 202. Although a single flywheel 212 is depicted near the end of the crankshaft 202, it should be understood that there may be more than one flywheel 212 and its location may be along any point along the center axis 204 of the crankshaft 202.

Although not depicted here, in some cases, the environment 200 may include a ring gear that may fit around the flywheel 212, such that the ring gear is static relative to the flywheel 212. In other words, the flywheel 212 and ring gear may rotate at the same rotational frequency. In other cases, the ring gear may be mechanically coupled to the crankshaft 202 by a mechanism other than the flywheel 212. Regardless of how the ring gear is coupled to the crankshaft 202, the optional ring gear may provide a mechanism for rotating the crankshaft 202 using an external motive element, such as a starter motor (not shown). Thus, the ring gear may enable starting the engine 106, when the engine 106 is not operational, by providing an initial kinetic energy from an outside source (e.g., a starter motor).

When the ring gear is mounted on the flywheel 212, it may appear that the combined entity is a flywheel with gear teeth projecting outward in the radial direction from the flywheel 212. The gear teeth of the ring gear may be engaged by a pinion (not shown) or small gear of an electric starter motor to provide an initial motion of the crankshaft 202 to start up the engine 106 of the machine 100.

The static seal 216 serves to hold fluids close to the crankshaft 202 during operation and also prevents and/or reduces dirt or other particles from contaminating the fluids retained near the crankshaft 202. As the crankshaft 202 rotates, the torque from the crankshaft 202 may cause fluids, such as lubricant, oil, synthetic oil, cooling fluids, transmission fluid, brake fluid, etc. to splatter away from the region 218 proximal to the crankshaft 202.

The fluids that are to be held in the region 218 near the crankshaft 202 may be important for the operation of the crankshaft 202. For example, the fluids in region 218 may reduce the overall friction of the crankshaft 202 during operation. Reduced friction, in turn, may reduce the operating temperature and improve the efficiency of the crankshaft 202 in its operation to turn reciprocating motion into rotational motion. Thus, retaining lubricating and/or heat dissipating fluids in proximity to the crankshaft 202 during operation provides operational benefits in greater power output and fuel efficiency, as well as lifetime and durability benefits of the crankshaft 202 and/or the components thereon. The static seal 216 reducing dirt or other particle intrusion in to the region 218 proximal to the crankshaft 202 improves the operational lifetime of those fluids.

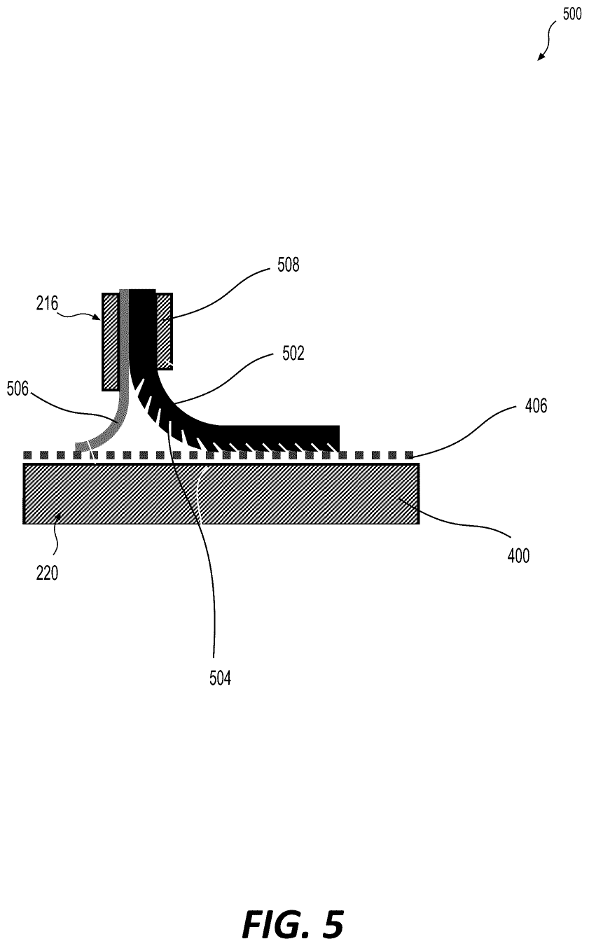

The static seal 216, as described in greater detail in conjunction with FIG. 5, includes one or more protruding elements, in a radial direction, that may obstruct fluids from escaping the region 218 proximal to the crankshaft 202 and/or prevent dirt from entering the region 218 proximal to the crankshaft 202. Since the crankshaft 202 rotates at a relatively high speed (e.g., greater than 100 rotations per minute (rpm)), the crankshaft 202 may deviate in the radial direction from the center axis 204. These small movements of the crankshaft 202 during operation may be enough to cause the crankshaft 202 to at least occasionally contact the static seal 216 or elements thereof. The contact between the crankshaft 202 and the static seal 216 can result to wear and tear of the static seal and/or elements thereof. As another concern, the contact between the crankshaft 202 and the static seal 216 may also cause wear and tear on the crankshaft 202 itself.

The wear sleeve 220, as disclosed herein, is disposed around the crankshaft 202 in a radial orientation and reduces the infirmities associated with the contact of the static seal 216 and the crankshaft 202. The wear sleeve 220, as a sacrificial element, prevents wear of the crankshaft 202 itself, resulting from contact with the static seal 216. However, a conventional wear sleeve can still cause wear of the static seal 216 in a manner similar to not having the wear seal at all. The wear seal 220, as disclosed herein, includes a coating on its outer diameter that contacts with the static seal 216 during operation. The coating on the wear sleeve 220 serves the purpose of reducing wear of the static seal 216 when contacted by the coated wear sleeve 220. Thus, by the use of the wear sleeve 220 disclosed herein, the operating lifetime of the static seal 216 may be enhanced relative to using a conventional wear sleeve or no wear sleeve at all. Additionally, the wear sleeve 220 with the coating, as disclosed herein, may enhance the operating lifetime of the crankshaft 202 and/or the wear sleeve 220 itself.

The bulk of the wear sleeve 220 may be constructed from metal, such as steel, stainless steel, and/or iron alloys. For example, the wear sleeve 220 may be constructed from any one of low-carbon steel, medium carbon steel, and/or high carbon steel. In some cases, the wear sleeve 220 may have a variable carbon-content due to treatments, such as carburization and/or hard facing. For example, in some cases, the wear sleeve 220 may have a tough low-carbon steel encased in hard high-carbon steel. In some cases, the wear sleeve 220 may be constructed from medium-carbon steel that is subsequently coated, according to the mechanisms and structure disclosed herein.

The coating on the wear sleeve 220 may be a diamond like carbon (DLC) coating. For example, the DLC coating may be a tetrahedral amorphous carbon (ta-C) type of DLC and/or amorphous A-C: H DLC. In some cases, the coating on the wear sleeve 220 may be metal-doped and/or metalloid-doped DLC (Me-DLC). For example, the coating on the wear sleeve 220, in some cases, may be tungsten (W)-doped DLC (W-DLC), titanium (Ti)-doped DLC (Ti-DLC), silicon (Si)-doped DLC (Si-DLC), and/or tungsten carbide (WC)-doped DLC (WC-DLC). The coating, as disclosed herein, may be a thin film that may be deposited by any variety of processes, such as physical vapor deposition (PVD) or other vacuum and/or plasma processes. Alternatively, the coating may include any variety of nitrides and/or carbides, such as CrN, TiN, TiAlN, TaN, VC, TiC, WC, TaC, etc.

The nature of the coating may be engineered for its tribological properties, hardness, toughness, and/or adhesion strength to the metal construction of the wear sleeve 220. The disclosure envisions the use of any of the variety of forms of DLC and/or Me-DLC for the coating on the wear sleeve 220. For example, the coating may include ta-C with sp³ bonded carbon (C) atoms. In other cases, the C may be bonded with different ratios of sp² and sp³ nature. The DLC and/or Me-DLC may be of any suitable structure, such as cubic, hexagonal, amorphous film, graphitic sheets, graphitic rolls (e.g., carbon nanotubes (CNT), spheres (e.g., Buckminster fullerene balls or buckyballs), combinations thereof, or the like. In some cases, a base layer may be deposited prior to the DLC and/or Me-DLC layer. The base layer may include, for example, Cr, Ti, or the like.

Regardless of the exact type and stoichiometry of the coating, the outer diameter of the wear sleeve 220, where the coating is disposed, may provide a lower friction surface than if the wear sleeve is not coated. In other words, the coating, as disclosed herein, effectively reduces the coefficient of kinetic friction (μₖ) and/or the coefficient of static friction (μₛ) between the wear sleeve 220 and the static seal 216. Thus, the reduced levels of friction between the parts in contact (e.g., the static seal 216 and the wear sleeve 220) result in reduced friction, heat, and wear of the static seal 216. Additionally, the wear sleeve 220 with the coating protects the crankshaft 202 from wear.

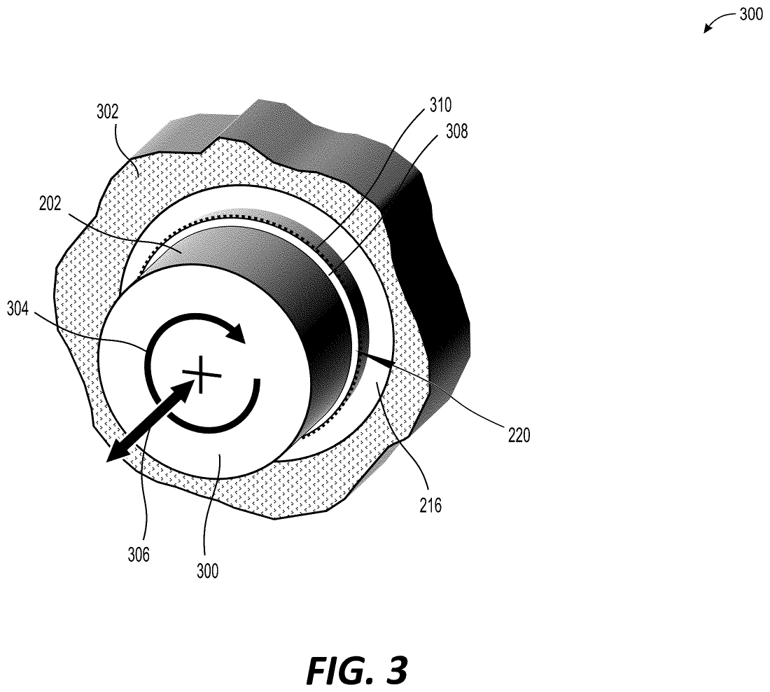

FIG. 3 is a schematic illustration of an end 300 of the crankshaft 202 of FIG. 2 within a housing 302 with the static seal 216 and a coated wear sleeve 220, according to examples of the disclosure. As shown, the static seal 216 may be mounted on the housing 302, proximal to a hole in the housing 302 through which the crankshaft 202 may pass. The wear sleeve 220 with coating, as disclosed herein, may be disposed on the crankshaft 202, such that the location of the wear sleeve 220 is substantially aligned with the location of the static seal 216, as mounted on the housing 302. In this way, the static seal 216 engages the rotating wear sleeve 220 to provide a low-leak seal of fluids in proximity to the crankshaft 202. It should be understood that in some cases, the housing 302 may be part of the engine 106 housing. It should further be understood that FIG. 3 is one example of how the crankshaft 202, coated wear sleeve 220, and the static seal 216 are aligned. The disclosure herein contemplates any other mechanism of spatial alignment of the crankshaft 202, coated wear sleeve 220, and the static seal 216.

During operation, the end 300 of the crankshaft 202 may rotate, such as in the direction indicated by arrow 304. It should be understood that in other cases, the crankshaft 202 may rotate in the opposite direction of arrow 304. As long as the crankshaft 202 rotates, there is a chance of relatively small movement of the crankshaft in a radial direction. However, even small excursions from the center axis 204 can result in the crankshaft 202 and/or the wear sleeve 220 contacting the static seal 216. Any type of contact between the static seal 216 and any rotating part 202, 220 will result in friction between the contacting parts. During operation, there may be contact between the static seal 216 and its corresponding wear sleeve 220, even if the static seal 216 and the wear sleeve 220 are properly aligned. The friction, in turn causes wear on one or both of the contacting parts 216, 220.

In addition to radial excursions, the crankshaft 202 may occasionally experience longitudinal excursions, as indicated by arrow 306. Thus, the crankshaft 202 may have some give of movement in the longitudinal direction relative to the housing 302 and/or the static seal 216. Therefore, the width of the wear sleeve 220 may be sufficiently wide to ensure alignment between the static seal 216 and the wear sleeve 220 accounting for any expected longitudinal movement of the crankshaft 202. If the wear sleeve 220 is not sufficiently wide, then the static seal 216, on occasion, may be aligned with, or even contact, the crankshaft 202 itself, without the intervening wear sleeve 220.

The wear sleeve 220 includes a bulk region 308 and a coating 310. As discussed herein, the bulk region 308 may be made of any suitable material, such as stainless steel, steel, iron alloy, aluminum, copper, titanium, other metals, combinations thereof, or the like. In some cases, the bulk region 308 may be formed from low- or medium-carbon steel. The bulk region 308 may be formed by any suitable process, such as casting, forging, extruding, machining, combinations thereof, or the like. The bulk region 308 may be of any suitable radium, width, and/or shape to fit the crankshaft 202 and to suitably engage the surrounding static seal 216.

The coating 310 may be any suitable material, such as DLC, Me-DLC, metalloid-DLC, non-metal-DLC, W-DLC, or the like. The coating 310 imparts tribological benefits to the wear sleeve 220 compared to just the bulk region 308 without the coating 310. The coating 310 reduces the level of friction, when the static seal 216 contacts the wear sleeve 220. In other words, the coating 310 reduces the effective coefficient of kinetic friction (μₖ) and/or the coefficient of static friction (μₛ) between the wear sleeve 220 and the static seal 216.

According to examples of the disclosure, the coating 310 may be deposited onto the outer diameter of the bulk region 308 by any suitable process, such as physical vapor deposition (PVD) or similar vacuum and/or physical processes (e.g., sputtering, evaporation, etc.). In some cases, a carbon (e.g., graphite target) may be prepared for the PVD deposition process. The bulk region 308 may be formed and then loaded on a rotating platen within a PVD chamber. The rotating platen may rotate the outer diameter of the bulk region 308 such that all portions of the outer diameter is in line of sight to the target(s) mounted above it for at least some period of time. While the bulk region 308 rotates within the PVD chamber, any suitable power may be applied to sputter material from the target(s) onto the outer diameter of the bulk region to form the coating 310. In some cases, a single target, containing both the C and the metal, may be used to deposit the Me-DLC film (e.g., W-DLC film). In other cases, two or more targets may be used to deposit the metal and C from separate targets. For example, a graphite target and a tungsten (W) target may be provided during the deposition process. The targets, in this case, may be rotated to ensure uniform deposition of W and C.

In other examples of the disclosure, PVD-enhanced chemical vapor deposition (CVD) and/or reactive sputtering may be used to deposit the Me-DLC film on the bulk region 308. Again, the bulk region 308 may be mounted on a rotating platen that exposes the edge or outer diameter of the bulk region 308 to the target within the PVD-enhanced CVD chamber and/or a reactive sputtering chamber. The chamber may have a metal target, such as a W target. The chamber may be powered and electrically biased in such a way that the W target is sputtered while C containing gases C (e.g., C₂H₄, C₂H₆, CH₄, etc.) are flown into the chamber to deposit the DLC. In this way, DLC is deposited by CVD, while sputtered metal (e.g., W, Ti, etc.) dopes the deposited DLC.

In yet other examples of the disclosure, a CVD process may be performed to deposit the DLC, Me-DLC, or non-metal-DLC as coating 310. The bulk region 308 may be provided in a vacuum chamber, such as a plasma enhanced chemical vapor deposition (PECVD) chamber and/or a plasma assisted chemical vapor deposition (PACVD) chamber. Power may be applied, and carbon containing gasses (e.g., C₃H₈, C₂F₆, etc.) and metal containing gasses (e.g., WF₆, trimethyl-silane, TEOS, etc.) may be flown into the chamber to strike a plasma and deposit the Me-DLC film as coating 310 on the outer diameter of bulk region 308.

In still other cases, the disclosure envisions using other mechanisms to deposit the coating 310 on the bulk region 308 of the wear sleeve. For example, atomic layer deposition (ALD) methods may be used, in some cases, to deposit coating 310. In other cases, thermal/plasma spray processes, such as a high velocity air fuel (HVAF) process or a high velocity oxygen fuel (HVOF) process may be used to deposit the coating 310 onto the bulk region 308. In still other cases, plating processes, such as an electroplating process or an electroless process, may be used to deposit the coating 310 onto the bulk region 308.

It should be understood that the coating 310 may be homogenous in some cases, where the composition, stoichiometry, density, or the like are substantially uniform throughout the thickness of the coating 310. In other cases, the coating 310 may be multi-layered, where there may be a variation in one or more of composition, stoichiometry, density, or the like along its thickness. The coating 310 may be multi-layered as a consequence of the deposition process, or intentionally, such as to alleviate stresses and/or to promote adhesion. In still other cases, the coating 310 may include a gradient in one or more of its composition, stoichiometry, density, or the like along its thickness.

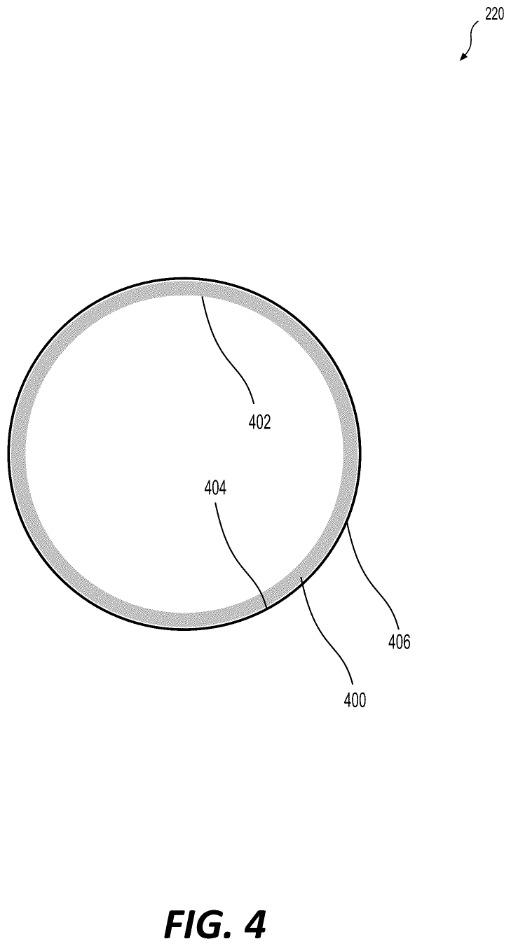

FIG. 4 is a schematic illustration of the coated wear sleeve 220, according to examples of the disclosure. The coated wear sleeve 220 may include a bulk region 400 with an inner diameter surface or inner surface 402 and outer diameter surface or outer surface 404. A coating 406 is disposed on the outer surface 404. The coating 406 may be an example of coating 310. In some cases, the entirety of the outer surface 404 of the bulk region 400 may be coated with the coating 406. When the coated wear sleeve 220 is assembled onto the crankshaft 202, the inner surface 402 of the coated wear sleeve 220 is in contact with an outer surface of the crankshaft 202. For example, the coated wear sleeve 220 may be disposed on the crankshaft 202 proximal to one of the ends of the crankshaft 202 such as end 300.

The bulk region 400 may be formed using any suitable type of steel, such as any variety of low-carbon steel, any variety of medium carbon steel, any variety of high-carbon steel, any variety of alloy steel, or the like. The bulk region 400 may be formed by any suitable mechanism such as any suitable hot formation mechanism and/or machining technique. For example, any type of casting, rolling, forging, extrusion, combinations thereof, or the like may be used to form the bulk region 400. Additionally, or alternatively, the rough component may be formed by any variety of machining techniques suitable for forming the component, such as any type of shaping, turning, milling, drilling, grinding, chiseling, lathing, and/or other machining techniques.

The coating 406 may include any of the variety of forms of DLC and/or Me-DLC. For example, the coating may include ta-C or other Me-DLC with relatively high levels of sp³ bonded C-to-C bonds. In other cases, the C may be bonded with different ratios of sp² and sp³ nature. The DLC and/or Me-DLC may be of any suitable structure, such as cubic, hexagonal, amorphous film, graphitic sheets, graphitic rolls, CNT, spheres, buckyballs, combinations thereof, or the like. In some cases, the coating 406 may cover only the outer surface 404 of the bulk region 400. In other cases, some other portions of the bulk region 400, other than the outer surface 404 (e.g., the sidewalls between the inner surface 402 and outer surface 404) may be at least partially coated with coating 406. In yet other cases, the entirety of the surface of the bulk region 400 may be coated with coating 406.

The coating 406 may be of any suitable thickness. In some cases, the thickness of the coating 406 may be in the range from about 0.25 micrometers (μm) to about 20 μm. In other cases, the thickness of the coating 406 may be in the range from about 0.5 μm to about 10 μm. In yet other cases, the thickness of the coating 406 may be in the range from about 0.5 μm to about 5 μm. In still other cases, the coating 406 may be in the range from about 1 μm to about 2 μm. In other example cases, the coating 406 may range from about 1 μm to about 5 μm.

The coating may be of any suitable hardness. In some cases, the hardness of the coating 406 may be in the range from about 10 Gigapascal (GPa) to about 20 GPa. In other cases, the hardness of the coating 406 may be in the range from about 10.5 GPa to 14.5 GPa. In still other cases, the hardness of the coating 406 may be in the range from about 11 GPa to 14 GPa. In yet other cases, the hardness of the coating 406 may be in the range from about 12 GPa to 13.5 GPa. In one example, the hardness of the coating may be approximately 13 GPa.

The coating may have any suitable tribological properties. In some cases, the coefficient of kinetic friction (μₖ) of the coating 406 may be less than about 0.35. In other cases, the μₖ of the coating 406 may be less than about 0.3. In yet other cases, the μₖ of the coating 406 may be less than about 0.25. In still other cases, the μₖ of the coating 406 may be less than about 0.2. In some cases, the μₖ of the coating 406 may be less than about 0.15. In some other cases, the μₖ of the coating 406 may be less than about 0.1. In yet other cases, the μₖ of the coating 406 may be less than about 0.07.

It should be appreciated that the coating 406 on the bulk region 400 enables a strong adhesion strength between the coating 406 and the bulk region 400, such as the outer surface 404 of the bulk region 400. In some cases, the C in the Me-DLC film may partially react with the outer surface 404 and/or diffuse partially into the outer surface 404 of the bulk region 400. This, in turn, provides for relatively strong adhesion of the coating 406 to the bulk region 400. Thus, the coating 406, in the form of DLC, Me-DLC, W-DLC, Ti-DLC, Si-DLC, H-DLC, B-DLC, F-DLC, or the like provides the advantages of reduced friction, increased hardness, and high adhesion strength. For the purposes of this disclosure, metal-DLC is understood to include metalloid-DLC, such as Si-DLC.

FIG. 5 is a sectional illustration of an example environment 500 with the coated wear sleeve 220 in contact with a static seal 216, according to examples of the disclosure. The static seal 216 may include a seal element 502, with grooves 504 cut therein, and a dust guard 506 held by a housing 508. As discussed herein, the seal element 502 and/or the dust guard 506 may contact with the coated wear sleeve 220, particularly at the coating 406.

As discussed herein, the improved tribological properties of the coated wear sleeve 220 may result in an improvement in the operating lifetime of the static seal 216. During normal operation of the machine 100, a wear sleeve may wear out the seal element 502 and dust guard 506, as there is relative movement, while in contact, between the seal element 502 and the wear sleeve, as well as between the dust guard 506 and the wear sleeve. However, due to the lower level of friction with the coated wear sleeve 220, as disclosed herein, the operating lifetime of the seal element 502 and the dust guard 506 may be improved, relative to conventional wear sleeves without a coating.

In some cases, the static seal 216 may have a 25% increase in its operating lifetime with the coated wear sleeve 220, when compared to the use of conventional wear sleeves. In other cases, the static seal 216 may have a 50% increase in its operating lifetime with the coated wear sleeve 220, when compared to the use of conventional wear sleeves. In yet other cases, the static seal 216 may have a 100% increase in its operating lifetime with the coated wear sleeve 220, when compared to the use of conventional wear sleeves. In still other cases, the static seal 216 may have a 200% increase in its operating lifetime with the coated wear sleeve 220, when compared to the use of conventional wear sleeves. In more cases, the static seal 216 may have a 300% increase or more in its operating lifetime with the coated wear sleeve 220, when compared to the use of conventional wear sleeves.

In some cases, the static seal 216, when using the coated wear sleeve 220, may have an operating lifetime of 6,000 hours or more. In other cases, the static seal 216, when using the coated wear sleeve 220, may have an operating lifetime of 10,000 hours or more. In still other cases, the static seal 216, when using the coated wear sleeve 220, may have an operating lifetime of 15,000 hours or more. In yet other cases, the static seal 216, when using the coated wear sleeve 220, may have an operating lifetime of 20,000 hours or more. In some cases, the static seal 216, when using the coated wear sleeve 220, may have an operating lifetime of 30,000 hours or more. In other cases, the static seal 216, when using the coated wear sleeve 220, may have an operating lifetime of 35,000 hours or more. In still other cases, the static seal 216, when using the coated wear sleeve 220, may have an operating lifetime of 40,000 hours or more.

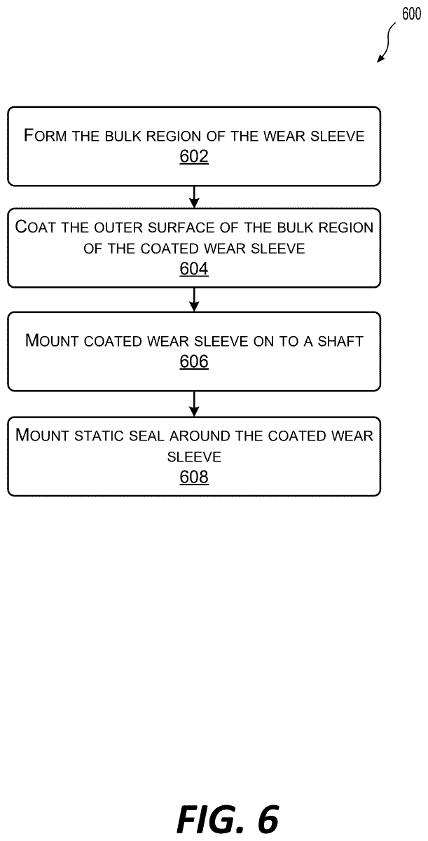

FIG. 6 is an example method 600 to form the wear sleeve of FIG. 4, according to examples of the disclosure. The method 600 may be performed in any suitable environment, such as a factory, or multiple locations. For example, the bulk region 308 and the coating 310 may be fabricated in separate facilities.

At block 602, the bulk region 400 of the coated wear sleeve 220 is formed. This is a formation of the bulk region 308 of the coated wear sleeve 220. For example, the bulk region 400 may be formed from any variety of steel, stainless steel, iron, other metals, ceramics, etc. The bulk region 400 may be formed by any suitable mechanism such as any suitable hot formation mechanism and/or machining technique. For example, any type of casting, rolling, forging, extrusion, combinations thereof, or the like may be used to form the bulk region 400. Additionally, or alternatively, the rough component may be formed by any variety of machining techniques suitable for forming the component, such as any type of shaping, turning, milling, drilling, grinding, chiseling, lathing, and/or other machining techniques.

The bulk region 400, during formation, may be any suitable crystal structure, such as ferrite, pearlite, bainite, cementite, martensite, and/or austenite. In some cases, the starting steel may have a relatively high level of relatively softer ferrite and/or pearlite crystal structure. The initial low, medium, or high carbon steel may be relatively soft and ductile, allowing for easier formation of the bulk region 400. In some cases, heating and quenching treatments may be performed to harden the steel construction of the bulk region 400. Other processes, such as tempering, annealing, carburizing, and/or hard facing may be used to attain the desired properties of the bulk region 400.

At block 604, the outer surface 404 of the bulk region 400 of the coated wear sleeve 220 is coated. As discussed herein, the coating 406 may be deposited on the outer surface 404 of the bulk region 400 using any suitable process. For example, a PVD or similar process may be used to deposit the coating 406 on the outer surface of the coated wear sleeve 220. Alternatively, a PVD-enhanced CVD and/or reactive sputtering process may be used. Other possible processes for depositing the coating 406, in the form of DLC, Me-DLC, W-DLC, Ti-DLC, Mo-DLC, Ta-DLC, Cr-DLC, Al-DLC, or the like, may be performed using CVD, PECVD, ALD, HVAF, HVOF, combinations thereof, or the like.

According to examples of the disclosure, the coating 310 may be deposited onto the outer surface 404 of the bulk region 400 by any suitable process, such as PVD or similar vacuum and/or physical processes (e.g., sputtering, evaporation, etc.). In some cases, a carbon target with metal (e.g., W) therein may be prepared for the PVD deposition process. The bulk region 400 may be loaded on a rotating platen within a PVD chamber. The rotating platen may rotate the outer surface 404 of the bulk region 400 such that all portions of the outer surface 404 is in line of sight to the target(s) mounted above it for at least some period of time. While the bulk region 400 rotates within the PVD chamber, any suitable power may be applied to sputter material from the target(s) onto the outer surface 404 of the bulk region 400 to form the coating 406. Various gases (e.g., argon, xenon, helium, oxygen, carbon dioxide, etc.) may be flown into the chamber to enable the PVD process. In some cases, a single target, containing both the C and the metal, may be used to deposit the Me-DLC film (e.g., W-DLC film). In other cases, two or more targets may be used to deposit the metal and C from separate targets. For example, a graphite target and a W target may be provided during the deposition process. When using multiple targets, the targets may be rotated to ensure uniform deposition of the metal and C. Process conditions may be adjusted to deposit the coating to a desired thickness.

In other examples of the disclosure, PVD-enhanced CVD may be used to deposit the Me-DLC film on the bulk region 400. Again, the bulk region 400 may be mounted on a rotating platen that exposes the outer surface 404 of the bulk region 400 to the target within the PVD-enhanced CVD chamber. The chamber may have a metal target, such as a W target. The chamber may be powered and electrically biased in such a way that the W target is sputtered while C containing gases C (e.g., C₂H₄) are flown into the chamber to deposit the DLC. In this way, DLC is deposited by CVD, while sputtered metal (e.g., W, Ti, Al, Cr, etc.) dopes the deposited DLC.

In yet other examples of the disclosure, a CVD process may be performed to deposit the Me-DLC as coating 406. The bulk region 400 may be provided in a vacuum chamber, such as a PECVD chamber. Power may be applied, and carbon containing gasses (e.g., CH₄, etc.) and metal-containing gasses (e.g., WF₆, TiCl₄, etc.) may be flown into the chamber to strike a plasma and deposit the Me-DLC film as coating 406 on the outer surface 404 of the bulk region 400.

In still other cases, the disclosure envisions using other mechanisms to deposit the coating 406 on the bulk region 400 of the wear sleeve. For example, atomic layer deposition (ALD) methods may be used, in some cases, to deposit coating 406. In other cases, thermal/plasma spray processes, such as a high velocity air fuel (HVAF) process or a high velocity oxygen fuel (HVOF) process may be used to deposit the coating 406 onto the bulk region 400.

At block 606, the coated wear sleeve 220 is mounted onto a shaft. The shaft, in some cases, may be the crankshaft 202. In some cases, the coated wear sleeve 220 may be slid on to the crankshaft 202 from one end 300 of the crankshaft 202. In some cases, the coated wear sleeve 220 may be friction-fitted on to the crankshaft 202. In other cases, the coated wear sleeve 220 may be held onto the crankshaft 202 by any suitable mechanism, such as epoxy, solder, screws, clips, other fasteners or the like.

At block 608, the static seal 216 may be mounted around the coated wear sleeve 220. In some cases, the static seal 216 may be mounted to a housing that houses part of the crankshaft 202, as depicted in FIG. 3. The disclosure, herein, envisions any suitable mechanism for aligning and holding the static seal 216 relative to the coated wear sleeve 220, and/or vice-versa.

It should be noted that some of the operations of method 600 may be performed out of the order presented, with additional elements, and/or without some elements. Some of the operations of method 600 may further take place substantially concurrently and, therefore, may conclude in an order different from the order of operations shown above.

### INDUSTRIAL APPLICABILITY

The present disclosure describes systems, structures, and methods to provide coated wear sleeves 220 for crankshafts 202 of engines, such as engine 106 of machine 100. A coating may be provided on the wear sleeve 220 of the crankshaft 202 of the machine 100 to provide a hard and low-friction surface. Since the coated wear sleeve 220 makes contact with a static seal 216 during the operation of the engine 106, the low-friction surface of the coated wear sleeve 220 results in reduced frictional forces between the static seal 216 and the rotating crankshaft 202. This reduced friction between the static seal 216 and the coated wear sleeve 220 results in extended lifetime of the static seal 216, compared to the use of conventional wear sleeves or no wear sleeves at all. The static seal 216 may last for four times or more longer, when using the coated wear sleeve, compared to conventional wear sleeves.

The reduced wear of the static seal 216 allows for longer periods of time between replacing the static seal 216. Longer times between replacement of the static seal 216 results in reduced field downtime, reduced frequency of servicing and maintenance, and overall reduced the cost of heavy equipment, such as machines 100. The improved reliability and reduced field-level downtime also improves the user experience such that the machine 100 can be devoted to its intended purpose for longer times and for an overall greater percentage of its lifetime. Improved machine 100 uptime and reduced scheduled maintenance may allow for more efficient deployment of resources (e.g., fewer, but more reliable machines 100 at a construction site). Thus, the technologies disclosed herein improve the efficiency of project resources (e.g., construction resources, mining resources, etc.), provide greater uptime of project resources, and improves the financial performance of project resources.

In addition to the improved lifetimes of the static seal 216, the hardness of the coating 406 of the coated wear sleeve 220 can lead to improved lifetime of the coated wear sleeve 220 itself, as well as the crankshaft 202. For example, the coated wear sleeve 220, as disclosed herein, may last the entirety of the lifetime of the machine 100.

Although the coated wear sleeve 220 is discussed in the context of a crankshaft 202 of a machine 100, the coated wear sleeve 220 may apply to any type of shaft that can benefit from a wear sleeve. For example, shafts of a transmission may have static seals to hold transmission fluid close to moving gears and other parts. These shafts within the transmission may have coated wear sleeve(s) 220 disposed thereon for similar purposes as discussed herein with respect to the crankshaft 202. Additionally, the coated wear sleeve 220 may be used in any variety of engines or motors used in applications other than machine 100, such as marine engines, car engines, or the like.

While aspects of the present disclosure have been particularly shown and described with reference to the embodiments above, it will be understood by those skilled in the art that various additional embodiments may be contemplated by the modification of the disclosed machines, systems and methods without departing from the spirit and scope of what is disclosed. Such embodiments should be understood to fall within the scope of the present disclosure as determined based upon the claims and any equivalents thereof.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein.

What is claimed is:

1. A shaft, comprising:
a first end and a second end opposing the first end, the first end and the second end spanning a length of the shaft; and
a wear sleeve disposed proximal to the first end and radially surrounding the shaft, wherein the wear sleeve comprises:
a bulk region having an inner diameter surface and an outer diameter surface opposing the inner diameter surface, and
a coating disposed on the outer diameter surface, the coating comprising diamond like carbon (DLC).

2. The shaft of claim 1, wherein the shaft comprises a crankshaft.

3. The shaft of claim 1, wherein the coating comprises a metal-doped DLC.

4. The shaft of claim 1, wherein the coating comprises tungsten (W)-doped DLC (W-DLC).

5. The shaft of claim 1, wherein the coating has a thickness of at least 0.5 micrometer (μm) and less than 20 μm.

6. The shaft of claim 1, wherein the wear sleeve rotates and is configured to be in contact with at least one of seal element or a dust guard of a static seal.

7. The shaft of claim 1, wherein the coating is characterized by a hardness exceeding 12 Gigapascal (GPa).

8. A machine, comprising:
an engine including a crankshaft with a coated wear sleeve disposed on the crankshaft, wherein the coated wear sleeve includes:
a bulk region having an inner diameter surface and an outer diameter surface opposing the inner diameter surface, and
a coating disposed on the outer diameter surface, the coating characterized by having a lower coefficient of static friction than the bulk region.

9. The machine of claim 8, wherein the coating comprises tungsten-doped diamond-like carbon (W-DLC).

10. The machine of claim 8, further comprising a static seal having at least one sealing element that contacts the coated wear sleeve during operation of the engine.

11. The machine of claim 10, wherein the coefficient of kinetic friction between the coating and the at least one sealing element is less than 0.2.

12. The machine of claim 10, wherein an operational lifetime of the static seal in contact with the coated wear sleeve is at least 6,000 hours.

13. The machine of claim 8, wherein the coating is characterized by a hardness exceeding 12 GPa.

14. The machine of claim 8, wherein the coating has a thickness between 1 micrometer (μm) and 2 μm.

15. A method, comprising:
forming a bulk region having a ring shape, the bulk region having an inner surface and an outer surface; and
depositing a coating layer over at least a portion of the outer surface to form a coated wear sleeve, the coating layer including metal-doped diamond-like carbon (Me-DLC).

16. The method of claim 15, further comprising:
mounting the coated wear sleeve on to a crankshaft.

17. The method of claim 16, further comprising:
mounting a static seal around the coated wear sleeve.

18. The method of claim 15, wherein depositing the coating layer further comprises:
depositing, by a physical vapor deposition (PVD) process using a target, the coating layer, the target including carbon.

19. The method of claim 18, wherein the PVD process uses a second target including tungsten (W).

20. The method of claim 15, wherein depositing the coating layer further comprises:
depositing the coating layer to a thickness between 1 micrometer (μm) and 2 μm.
